(19) United States
(12) Patent Application Publication
(10) Pub. No.: US 2023/0284690 A1
(43) Pub. Date: Sep. 14, 2023

(54) Electronic Cigarette

(71) Applicant: Carnault AG, Basel (CH)

(72) Inventors: Benjamin Kaiser, Basel (CH); Tobias Kaiser, Basel (CH); Stefan Bauer, Tubingen (DE); Daniel Brock, Chemnity (DE); Michael Schwitzer, Lichtenau (DE)

(21) Appl. No.: 18/011,496

(22) PCT Filed: Jun. 18, 2020
(86) PCT No.: PCT/EP2020/067041

§ 371 Date: Dec. 19, 2022

(51) Int. Cl. A24F 40/42; A24F 40/51; A24F 40/90; A24F 40/10

(52) U.S. Cl. CPC A24F 40/42; A24F 40/51; A24F 40/90; A24F 40/10

(57) ABSTRACT

An electronic cigarette comprises along a central Z-axis from bottom to top a cartridge unit and a control unit detachably arranged thereon, wherein the electronic cigarette includes a control unit for control and a battery unit for electronic power supply the battery unit having a battery cell having a negative pole and a positive pole spaced apart therefrom by an insulator. A negative contact and a positive contact are arranged on the control unit such that they are connected to the corresponding negative pole and positive pole, respectively, of the battery cell. The control unit has a geometric spatial structure perpendicular to the central Z-axis with a diameter, with which diameter the control unit forms a snug fit in the electronic cigarette.

The present application is the U.S. national phase of PCT Application PCT/EP2020/067041 filed on Jun. 18, 2020, which is incorporated herein by reference in its entirety.

### FIELD OF THE INVENTION

The present invention falls within the field of daily living and relates to an electronic cigarette.

### BACKGROUND

Conventional electronic cigarettes are hand-held devices which generate an inhalable aerosol from a precursor composition using electrical energy. For this purpose, each electronic cigarette has at least the following functional elements: an energy source, electronic control components, a precursor composition and an atomizer device. The latter may comprise a heating element (e.g. filament or heating chip) or other assembly capable of converting the precursor composition into an aerosol, for example by means of an ultrasonic atomizer or by means of a single- or dual-substance atomizer nozzle. The precursor composition may on the one hand consist of the aforementioned liquid or on the other hand contain solid components, such as prepared tobacco products (so-called heat-not-burn products).

Electronic cigarettes are designed to be used in the same way as traditional tobacco cigarettes. A scenario of use, as is the rule for the consumption of a traditional tobacco cigarette and therefore within the range of expectability for electronic cigarettes, would consist in inhaling the aerosol produced by the electronic cigarette several times in succession, with short pauses between each puff. Such a process, whereby the electronic cigarette is usually held in the hand, brought to the mouth and finally the aerosol in the form of a kind of mist or vapour is inhaled and in parts exhaled again, is also influenced by a desirable visibility and perceptibility to outsiders. Smoking traditional tobacco cigarettes has been and continues to be heavily advertised in many parts of the world. Attempts have been and are sometimes made to associate it with positive values such as sociability, authenticity and freedom. The global success of traditional tobacco cigarettes, which is expressed in the high number of consumers of more than one billion people, could be a sign that this attempt has at least partially succeeded. The fact that smoking tobacco cigarettes is extremely widespread, but not the use of similarly effective, often cheaper and in some cases far less harmful nicotine-containing products, such as oral tobacco, suggests that the high visibility and perceptibility of the smoking process and the product has a significant influence on its success or its ability to be associated with positive values.

These considerations lead to the conclusion that the success of an electronic cigarette is also highly dependent on the external perception of the product itself and on the external perception during the use of the product. In the same sense, it can be concluded that the design is also decisive for the question to what extent an electronic cigarette can be credibly associated with the very values that have helped the tobacco cigarette to achieve said success. It should be noted that these values described above can at least be described as timeless, since they are fundamental values for people, extensively and intensively discussed in almost every culture, and it can be assumed that they will also be relevant in the future. The product design is thus an essential differentiating feature both from other electronic cigarettes and from traditional tobacco cigarettes, and can possibly be the only distinguishing criterion that is visible to the outside world. It can therefore be a decisive advantage if an electronic cigarette is characterized by one or more of the following aspects, namely a high-quality choice of materials for the externally visible components, a high quality of workmanship, a long service life, possibilities for individualizing the external design, for example by making components interchangeable, a small product size that accommodates a pleasant handiness or feel and easy handling. dimensions that are as close as possible to the shape and size of a classic tobacco cigarette, as it can be assumed that many people are used to the shape and size of classic tobacco cigarettes and also to their weight. Furthermore, aspects such as environmental friendliness, waste minimization, recyclability and waste separation of materials are important today. The same applies to the choice of materials. Selected materials, such as wood or ebonite, are well known to smokers from cigarette-related products such as tobacco pipes, which means that the use of such materials in electronic cigarettes could also evoke a familiarity among smokers.

Furthermore, control electronics in the electronic cigarette are intended to ensure reliable and safe functioning of the aerosol generation and, if necessary, to comprise extended functions, such as, for example, the possibility of a Bluetooth connection to a smartphone or an authentication of the consumable in a so-called cartridge and, furthermore, a quantity control; the extended scope of functions is directly accompanied by an increased space requirement for electronic components or for electronic components, e.g. for more complex circuit structures in and around integrated circuits [IC—integrated circuits]. In addition, such control electronics comprise a switch-on element in the form of a switch, pushbutton or sensor which is capable of registering a draught of air from the customer (e.g. pressure sensor, air flow sensor, temperature sensor), as well as, where appropriate, display elements, such as an LED, and components for evaluation. Furthermore, the modularity of electronic cigarettes for the purpose of replacing individual components in the event of further developments and improvements or in the event of damage is an advantage. For this purpose, various interfaces and contacts are required, which may necessitate additional space.

In the case of a rechargeable battery cell, a high current that can be called up and a usable capacity that is as high as possible are advantageous as a source of energy. This is accompanied by the positive correlation between battery capacity and maximum discharge current, as well as the usually disadvantageous positive correlation between capacity, maximum discharge current and a correspondingly large volume or mass of such a rechargeable battery cell.

Of course, with a view to low production costs, economic aspects are not ignored, which are based on correspondingly simple assembly, low-cost components or a high degree of automation.

Some of the above-mentioned requirements for electronic cigarettes are in conflict with each other and thus require a trade-off between the advantages that must be fulfilled and the disadvantages that are of secondary importance.

For example, the use of natural materials such as wood or ebonite means that a certain minimum wall thickness cannot be undershot, which is greater than for stainless steel or other metals and alloys, so that tubes made of wood or ebonite, for example, require more space. In order to remain as faithful as possible to the shape and size of a tobacco cigarette and at the same time to be able to realise a technically advanced electronic cigarette, this makes a space-saving design inevitable.

Furthermore, a circular cylindrical housing shape, for example, means that the battery cell must also be circular cylindrical in order to fit optimally into this shape. However, at least for small cell sizes, cuboid battery cells with a higher capacity can be realized for the same volume than circular cylindrical battery cells. This is due to the basic layer structure of battery cells. In a round cell, the electrode and separator layers are usually rolled up, resulting in an unused cavity in the middle due to the limited angle of curvature of the layers used. This makes efficient use of space in a circular cylindrical housing all the more important. A cuboid housing design also accommodates the construction of printed circuit boards. A flat and rectangular PCB shape is easier to implement without sacrificing size or functionality, and at the same time can be integrated space-efficiently into a cuboid housing. The electronic components with which the printed circuit board of a control unit is equipped are often rectangular themselves, so they can be arranged more efficiently on a rectangular printed circuit board surface than on a round one. A rectangular housing is therefore more suited to the design of battery cells and printed circuit boards than would be the case with a circular-cylindrical housing and would, for example, simplify the conflict of objectives of small product size, the most powerful battery cell possible and good space utilisation of the printed circuit board. As a consequence, however, one moves away from the goal of similarity to the tobacco cigarette.

From the point of view of sustainability and economy, the use of high-quality materials or investing in a high quality of workmanship only makes sense if the corresponding components have a certain durability. Consequently, it would be disadvantageous if the service life of a battery sleeve, which takes up most of the visible surface area when the electronic cigarette is assembled and represents a central design object, were linked to the comparatively limited service life of the battery cell located inside it if both parts were permanently connected to each other. In order to be able to apply a high quality of workmanship and the use of high-quality materials, especially in the area of the battery sleeve, in a sensible, sustainable and economical manner, a modularly separable structure of the control electronics or control unit, the battery cell and the battery sleeve is a prerequisite. A high degree of modularity here regularly conflicts with a small product size, since the individual parts must have separable mechanical and electrical connections, which generally take up additional space. Furthermore, as higher demands are placed on the design, it may become more complex: more and/or more complex components may be needed, or it may require a greater number of steps for manufacturing, which would have a negative impact on final assembly and production costs.

The most powerful battery cells possible stand in the way of the highest possible functionality of the control electronics and a small product size. Simple assembly of the electronic cigarette can be at odds with increasingly complex control electronics, which sometimes results in the use of flexible printed circuit boards or diverse wiring and additional parts for connecting the printed circuit board to the housing, for example injection moulded parts, etc.

A simple technical operation may also have a negative impact on the space requirement and the product size, while it is also desirable that the electronic cigarette remains in an assembled and quasi-functional state while the battery is being charged. In this regard, such chargeability may take up additional space as opposed to a permanent closure that does not depict additional functions, for example because additional wiring may be required. Similarly, increased functionality or electrical design requirements may result in increased space requirements. For example, detecting changes in air pressure or air flow during smoking, so that the electronic cigarette can be used in the same way as a tobacco cigarette, requires air flow management. Often, additional components are used in addition to a pressure sensor.

A known electronic cigarette is disclosed in WO 2015/130598, wherein the electronic cigarette consists essentially of two parts connected in separable engagement, namely the control unit and the cartridge unit, which is also referred to as the cartridge unit. The control unit comprises a battery sleeve, a battery cell and a closure unit. The closure unit includes a circuit board aligned parallel to a longitudinal axis of the electronic cigarette, and further, the closure unit includes a non-separable connection on the battery sleeve.

The electronic cigarettes in the printed publications U.S. Pat. No. 10,111,470 B2 and WO 2016/127401 also essentially comprise two parts connected to each other in separable engagement, the control unit and the cartridge unit, in which the respective control unit is non-detachably sealed and thus it is not possible to replace individual parts of the control unit after the respective electronic cigarettes have been assembled ready for use.

In EP 3 130 238 B2, another conventional electronic cigarette comprises, essentially from top to bottom, an upper unit with a mouthpiece, a vaporizer core, a liquid container and, finally at the bottom, a control unit in the form of a power and control unit. Here, it is provided that the control unit includes a battery cell for supplying power and the control unit for controlling the electronic cigarette, said control unit being non-detachably closed by means of an upper support. Furthermore, a USB port is fixedly mounted on this control unit, which allows charging of the battery cell via the control unit which is also fixedly mounted in this control unit. The control unit also has an externally operable switch/button by means of which the electronic cigarette can or must be put into operation. The control unit can—as proposed—consist of a single or multi-layer printed circuit board, which can be arranged transversely to the longitudinal extension of the electronic cigarette.

The disclosed prior art has in common that the disclosed electronic cigarettes, in particular with regard to their respective control units, each comprising a battery cell and a control unit, represent segments which are not detachably closed from the outside, whereby the service life of such a control unit is necessarily designed for the respective weakest and thus shortest-lived individual part on or in these control units; the shortest-lived individual part in such a control unit may be the battery cell, or the control unit, with any switches/pushbuttons or electrical connections arranged thereon, such as a battery cell or a control unit, for example. the shortest-lived component in such a control unit may be the battery cell, or the control unit, with switches/buttons or electrical connections, such as a USB connector, arranged thereon. Furthermore, currently available products of electronic cigarettes are formed according to respective proprietary designs and thus differ greatly from the geometry and from the size of conventional tobacco cigarettes.

### SUMMARY

It is therefore the object of the present invention to further develop an electronic cigarette in such a way that a higher degree of interchangeability of individual components is achieved and a similarity to the geometry and size of conventional tobacco cigarettes is achieved by an improved use of space of components of the electronic cigarette and, furthermore, a simpler assembly is made possible compared to conventional electronic cigarettes.

The problem underlying the invention for the electronic cigarette is solved by the features of claim 1; the features further developing this inventive idea are in each case the subject of subclaims 2 to 11.

Advantageously, the electronic cigarette according to the invention has a cartridge unit and a control unit detachably arranged thereon along a central Z-axis from bottom to top, the electronic cigarette comprising a control unit for control and a battery unit for electrical supply, the control unit having a geometrical spatial structure with a diameter perpendicular to the central Z-axis, with which diameter the control unit forms a snug fit in the electronic cigarette; that means that the control unit efficiently utilizes or fills the space available to it in the electronic cigarette transversely to the central Z-axis and thus, after ready-to-use assembly, constitutes a compact unit with the control unit. and thus forms a compact unit with the control unit after ready-to-use assembly. In this way, the electronic cigarette according to the invention has an improved use of space compared to the prior art and also a higher degree of modularity. Furthermore, the control unit can be replaced if necessary, so that, for example, a new control unit can replace an older control unit both in the event of damage or for a functional extension, without further individual parts which are in a mechanical and/or electrical operative connection with the control unit necessarily also having to be replaced. This measure increases the service life of the electronic cigarette according to the invention and also takes into account the increased environmental awareness by conserving resources.

An advantageous embodiment provides that the fit formed between the electronic cigarette and the control unit is formed as a clearance fit, wherein the control unit is just slightly slidably arranged in the electronic cigarette. In this regard, it may be advantageous if the control unit has a +pole contact surface towards the bottom which is in electrical operative connection with an inner tube of the control unit. Furthermore, it is advantageous if the control unit is fixed in a closure component by means of a detachable press ring, which closure component is in turn detachably arranged in the control unit, and wherein the +pole contact surface of the control unit is in downwardly active electrical connection with the inner tube of the control unit by means of the press ring and the closure component.

In a further, advantageous embodiment of the electronic cigarette, it is provided that the fitting seat formed between the electronic cigarette and the control unit is formed as a transition fit, wherein the control unit can be inserted into the electronic cigarette with low pressure or can be pushed out of the electronic cigarette with low pressure. Further advantages are to be found in the fact that the control unit has a circumferential surface contact on an outer circumference, the control unit forming the fitting seat, which is designed as a transition fit, with a closure component by means of this circumferential surface contact and being in electrical operative connection with an inner tube of the control unit in the process.

Another advantageous embodiment of the invention provides that the control unit comprises at least one printed circuit board insulated from the electronic cigarette by means of an insulating filling, said at least one printed circuit board being oriented transversely to the Z axis. In this way, the at least one printed circuit board insulated from the outside constitutes the control unit and, as such, uses the space provided for this purpose in the control unit approximately completely, in the manner of assembly according to a fit.

Furthermore, a further embodiment according to the invention is characterized in that, on the one hand, one or more sensors, one or more electronic components and/or one or more microcontrollers are in electrical operative connection with one another on the printed circuit board and, on the other hand, electrical operative connections also exist with external contacts on the control unit, such as, for example, the +pole contact or the −pole contact facing upwards or the +pole contact surface facing downwards, via through-contacts in the form of conductor tracks.

Of particular advantage is that further embodiment in which the control unit is designed as a compact integrated electronic unit with one or more printed circuit boards equipped on one or both sides and electronic components enclosed, for example, with printed circuit board material, in order thus to be able to provide the greatest possible number of functional units for the electronic cigarette in the smallest possible spatial unit. The control unit is a system of electronic components (system-in-board) undetachably embedded in a three-dimensional structure of conductive electrical connections and insulating material, e.g. in a multilayer printed circuit board, the electronic components being protected from mechanical stresses as well as other environmental influences by their embedding. Embedding also provides significantly improved protection against manipulation of the electronic system as well as protection against other external access. The resulting compact, one-piece system is significantly more reliable, enables easier assembly and thus contributes significantly to the ease of replacement of this assembly, e.g. by a customer.

In a suitable embodiment of the control unit, the latter has a circular cross-section, the Z-axis of the electronic cigarette coinciding with the central axis of this control unit; the external geometry of the control unit which is then present then appears to be pot-like, button-battery-like or tablet-like, so that this control unit is also referred to hereinafter as a ladder plate tablet.

Further advantageous embodiments are highlighted with reference to the following figures in connection with the detailed description of the invention.

### BRIEF DESCRIPTION OF THE DRAWINGS

In the following, the invention is explained by way of example with reference to figures. Identical objects in the figures are generally provided with the same reference signs. At this point it is pointed out that the figures have no limiting effect on the subject matter of the invention, but merely represent possible embodiments of the idea of the invention.

It shows purely schematically the

FIG. 1 a sectional view of the electronic cigarette according to the invention with a central Z-axis for the purpose of a simple description when locating individual elements of the cigarette by means of the terms “top”, “bottom”, “upwards”, “downwards”, “upper end”, “lower end”, “upper side”, “lower side”, etc., which are also partly used here in the figures;

FIG. 2a an enlarged sectional view of the upper part of the electronic cigarette according to FIG. 1;

FIG. 2 an embodiment of the upper part of the electronic cigarette in an enlarged sectional view as shown in FIG. 1;

FIG. 3 an additional, enlarged sectional view of the electronic cigarette according to FIG. 1 with an associated control unit;

FIG. 4a further sectional view according to FIG. 2a with electrical connection paths;

FIG. 4a sectional view of the embodiment according to FIG. 2b with electrical connection paths;

FIG. 5 a sectional view of the control unit with its external electrical contacts according to FIG. 2a;

FIG. 6 a greatly enlarged sectional view of the control unit of the electronic cigarette;

FIG. 7a perspective view of the control unit looking at its top;

FIG. 8a perspective view of the control unit looking at its underside;

FIG. 9a perspective side view of a closure component with a control unit arranged therein;

FIG. 10 another embodiment of the closure component according to FIG. 9; and

FIG. 11 an even further embodiment of the closure component according to FIG. 9.

### DETAILED DESCRIPTION

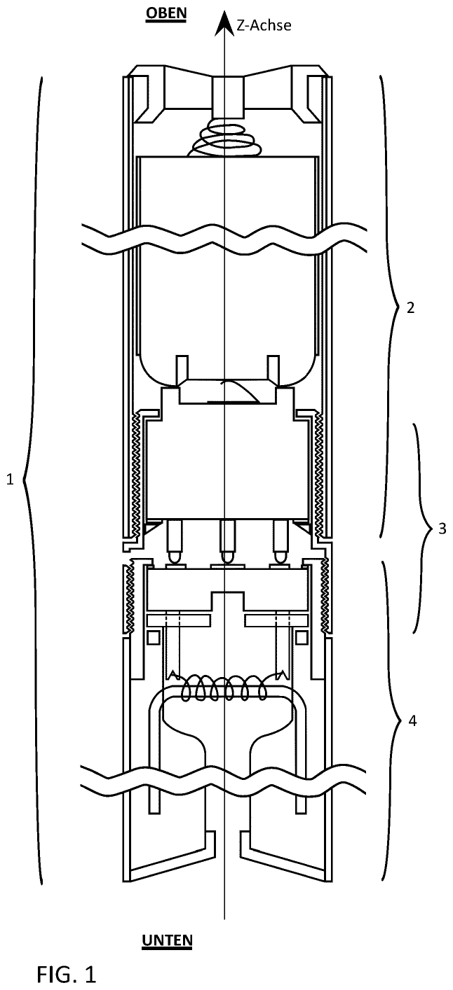

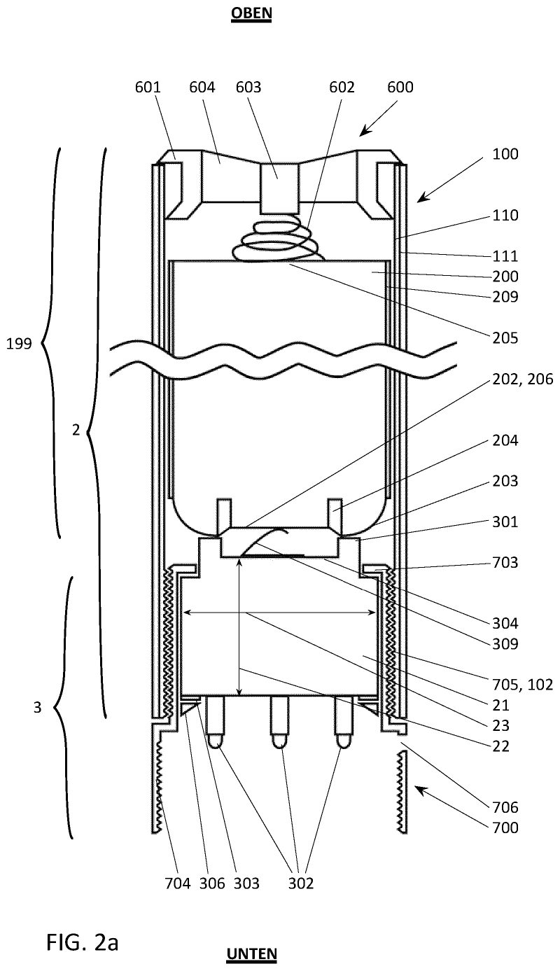

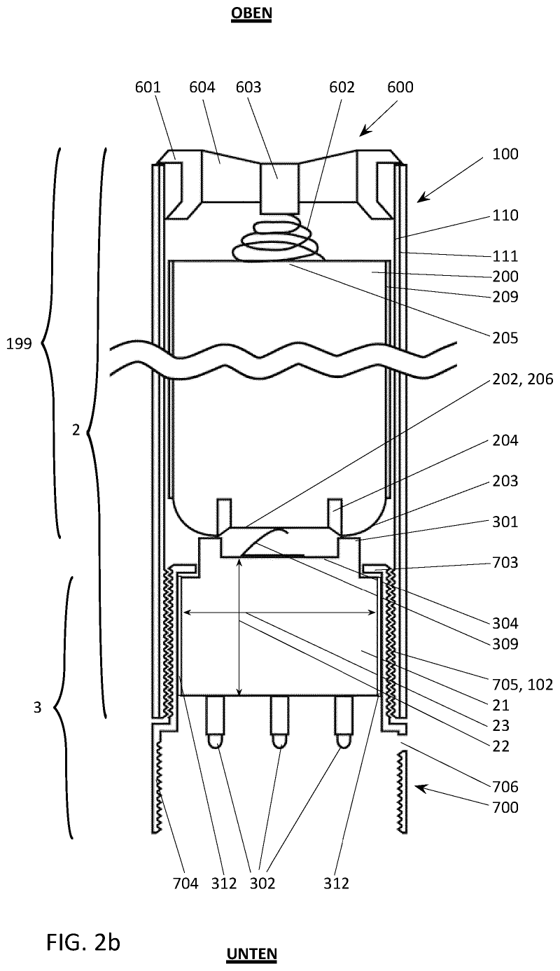

FIG. 1 shows the electronic cigarette 1 according to the invention in a sectional view with a central Z-axis from bottom to top for the purpose of a simple description in locating individual elements of the electronic cigarette 1, using the terms mentioned here and partly also in further figures, “top”, “bottom”, “towards the top”, “towards the bottom”, “upper end”, “lower end”, “top side”, “bottom side”, etc.; throughout the descriptive text, all of these place names refer to the orientation of the Z-axis, which is a central axis of the present electronic cigarette. In sequence from bottom to top, the electronic cigarette 1 comprises at least a cartridge unit 4 (also known as a “cartridge unit”) and a regulating unit 2 comprising a control unit 21 for controlling the electronic cigarette 1 and a battery unit 199 for supplying electronic power, see also FIG. 2a and FIG. 2b, respectively. Not necessarily—but shown in the present embodiment—the electronic cigarette 1 may have a closure unit 3 connecting the two units, cartridge unit 4 and control unit 2, which closure unit 3 extends upwards partly into the regulating unit 2 and downwards partly into the cartridge unit 4.

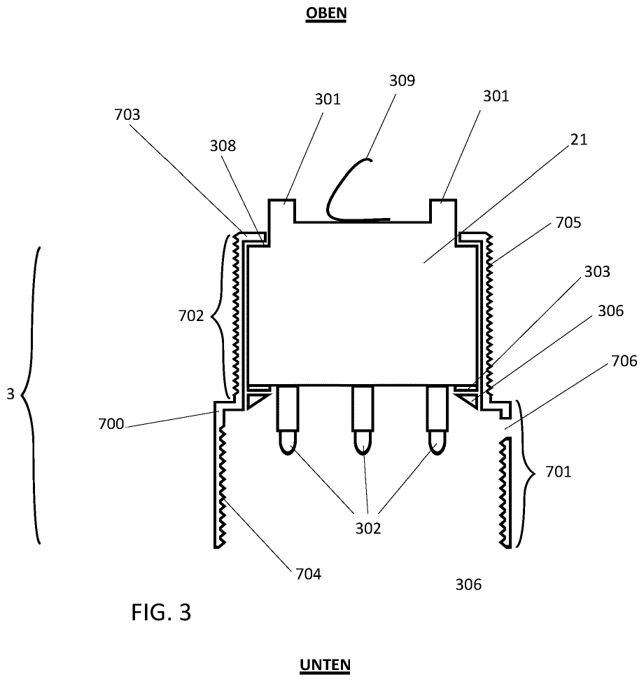

The enlarged sectional view of the upper part of the electronic cigarette 1 in FIGS. 2a, 2b shows a battery unit 199 with a battery cell 200 in a battery sleeve 100, which terminates at the top towards the tip of the electronic cigarette 1 with a charging tip 600 by means of an associated +pole contact ring 601, a ring insulator 604 and an −pole contact tip 603. At the bottom the regulating unit 2 is closed by the control unit 21. In the present case, this control unit 21 is arranged in a closure component 700 of the closure unit 3, this closure component 700 being screwed in an upper section 702 —see also FIG. 3—by means of an external thread 705 to an internal thread 102 of the control unit 2. As already mentioned above, the present embodiment with the control unit 21 of the regulating unit 2 in the closure component 700 is shown merely as a particularly suitable embodiment, whereas any other connection embodiment or fixing embodiment is also possible without any inventive contribution. On the other hand, any other connection embodiment or fixing embodiment is conceivable without an inventive contribution and is considered to be encompassed by the present invention; in this context, a direct arrangement of the control unit 21 in the regulating unit 2 is of course also conceivable, namely without the closure unit 3; further possibilities of representation in the form of correspondingly text-accompanied, further figures are dispensed with here, since they would not represent a broader idea of the invention than is the case here.

On the other hand, the arrangement of the control unit 21 in the electronic cigarette 1 in the form of a releasable fit is of importance; in the embodiment of FIG. 2a, for example, it is a fit with a clearance fit, wherein the control unit 21 is arranged so as to be just slightly displaceable in the electronic cigarette 1, and in the embodiment of FIG. 2b, it is a fit with a transition fit, wherein the control unit 21 can be inserted into the electronic cigarette 1 with slight pressure or can be pushed out of the electronic cigarette 1 with slight pressure.

Against the background of the new fits used here, in conjunction with the above-mentioned advantages with regard to miniaturization in the control unit 21, the latter fulfils all the conditions for the best possible utilization of space in the electronic cigarette according to the present invention.

Downwardly, the control unit 21 in FIG. 2a, which is arranged with a fit in the form of the clearance fit, has a +pole contact surface 303 or a +pole ring contact 303. The control unit 21 is fixed downwardly by means of a releasable press ring 306, which fixes the control unit 21 against an overhang 703 as a stop surface on the closure component 700. The internal thread 102 of the regulating unit 2 is arranged at a lower end thereof in an inner tube 110, which inner tube 110 is surrounded by an outer tube 111. This outer tube 111 is the outwardly largest visible part of the electronic cigarette 1 and thus enjoys a special status with regard to an outwardly effective design and consequent perception for the user as well as for third parties. In contrast to FIG. 2a, the embodiment in FIG. 2b shows the control unit 21 arranged with a snug fit in the form of the transition fit, which is fixed to the closure component 700 with slight pressure against the overhang 703 as a stop surface. At the outer circumference, the control unit 21 has a lateral surface contact 312 which serves, on the one hand, for the snug fit and, on the other hand, for the electrical contacting, wherein this lateral surface contact 312 —within the scope of the present invention—can completely or merely partially cover the outer circumference of the control unit 21. In embodiments not shown in more detail here, it is also conceivable within the scope of the present invention for the control unit to enter into a positive connection with the electronic cigarette, for example in the form of a tongue-and-groove connection or in the form of a bayonet lock, with which the control unit could be inserted in such a way as to be secured against rotation or, in the case of the clearance fit, also against slipping out independently.

In both embodiments of FIGS. 2a, 2b, the battery cell 200 supports a −pole 205 at its upper termination against a spring contact 602 toward the −pole contact tip 603 of the charging tip 600. Since the battery cell 200 in its typical embodiment has a metallic outer surface, the −pole 205 continues downwardly to a −pole ring contact surface 203. Opposite the inner tube 110, the battery cell 200 has an insulating plastic film 209. A+pole 202 is located in the center of the lower termination 206 of the battery cell 200, which is insulated from the −pole ring contact area 203 by an insulator ring 204. The battery cell 200 contacts with its −pole ring contact surface 203 and the +pole 202 the upwardly directed electrical connections of the control unit 21 at a −pole contact 301 and at a +pole contact 309, respectively, which is formed here as a +pole spring contact 309.

FIG. 3 shows the control unit 21 in an enlarged representation, using the example of the embodiment in FIG. 2a, although the following features apply to both embodiments in FIGS. 2a, 2b, namely that the closure unit 3 on the one hand accommodates the control unit 21 in the upper section 702 and on the other hand terminates at the bottom in a lower section 701 with an internal thread 704, on which —see also FIG. 1—the cartridge unit 4 engages. Due to the enlarged representation, an air inlet 706 is also visible here in the closure component 700, and furthermore a number of contact pins 302 which, starting from the control unit 21, point downwards to the cartridge unit 4 not shown here.

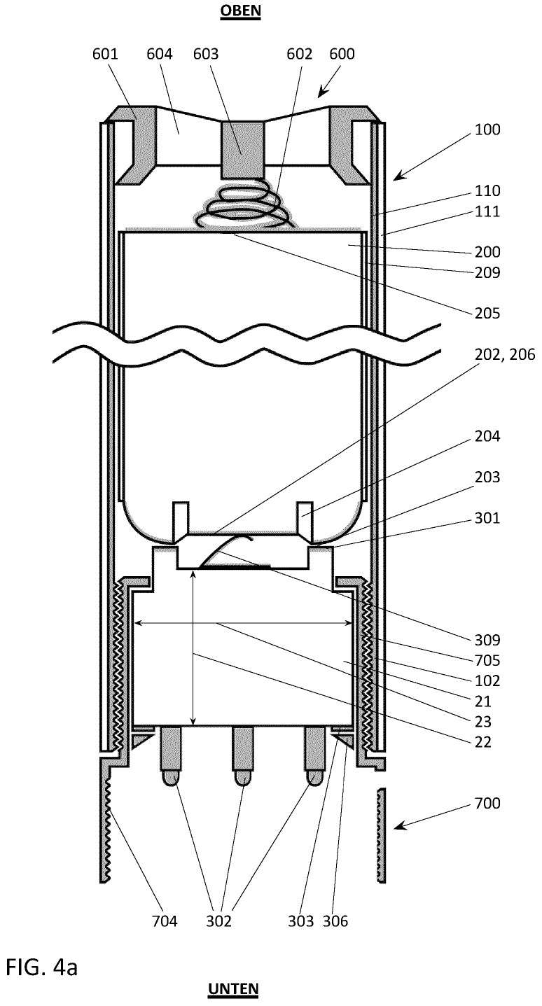

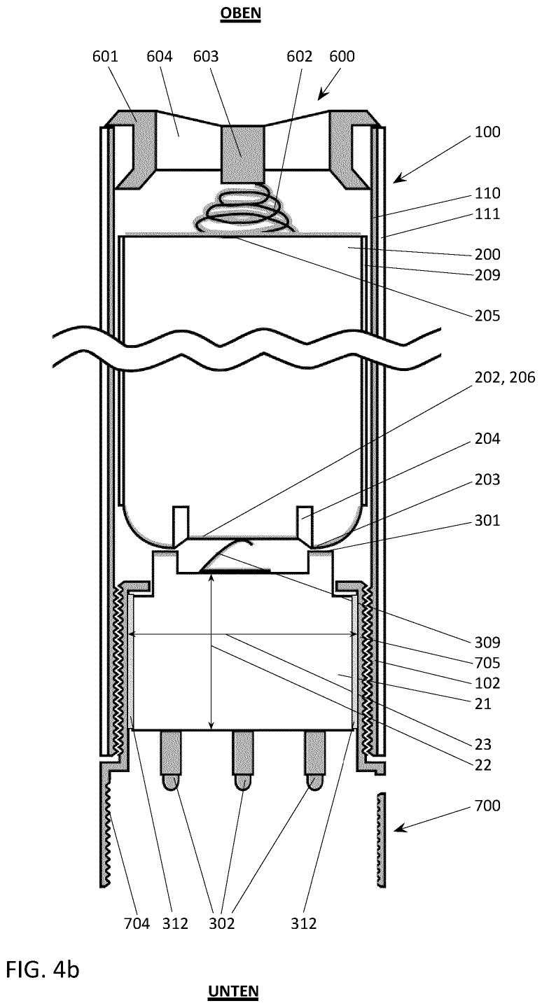

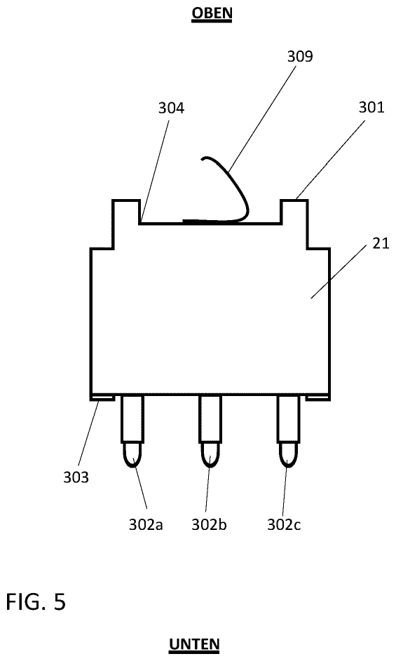

In FIGS. 4a, 4b, electrically relevant connections of the electronic cigarette 1 are summarized. In addition to the electrically effective contacts or elements already explained above, namely the +pole contact ring 601, the ring insulator 604, the −pole contact tip 603 with associated spring contact 602 of the charging tip 600, the −pole 205 at the upper termination of the battery cell 200 and the −pole ring contact surface 203 which is formed by means of a housing at the lower termination of the battery cell 200 and is spaced from the +pole of the battery cell by means of an insulator ring 204, the latter correspondingly contacting the control unit 21 at its −pole contact 301 and +pole spring contact 309, respectively, further electrical conduction paths or connection paths result. +pole spring contact 309, further electrical conduction paths or connection paths result. In FIG. 4a, the compression ring 306 is designed to be electrically conductive and thus connects the +pole ring contact 303 at the lower termination of the control unit 21 to the electrically conductive closure component 700, which provides a +pole connection via the conductive inner tube 110 to the charging tip 600 via the connection “external thread 705 on the closure component 700 and internal thread 102 on the battery sleeve 100”. As mentioned above, the battery cell 200 is surrounded by means of a plastic film 209 which is insulatingly effective with respect to the inner tube 110 of the battery sleeve, whereby a +pole connection to the charging tip 600 is passed quasi parallel thereto, namely up to the +pole contact ring 601 thereof. Accordingly, the sheath contact 312 is connected to the electrically conductive closure component 700, which also provides a +pole connection via the conductive inner tube 110 to the charging tip 600 via the connection “external thread 705 on the closure component 700 and internal thread 102 on the battery sleeve 100”. The following FIGS. 5 to 10 illustrate further features of the invention, but only with reference to the example of the embodiment in FIG. 2a or FIG. 4a, since these further features are valid for both embodiments of FIG. 2a, 2b or 4a, 4b and a multiple description of identical features is dispensed with.

FIG. 5 shows the control unit 21 in a stand-alone representation, the geometry of which can be described as essentially pot-shaped, button battery-shaped or tablet-shaped, with electrical contacts at the upper or lower end of this control unit 21. The pin contacts 302a, 302b and 302c are referenced downwards by way of example, with which reference is to be made to their —present here—different electrical function; the pin contact 302a is presently designed as a −pole spring contact pin, the pin contact 302b as a communication spring contact pin and the pin contact 302c as a +pole spring contact pin, whereby all three point to the cartridge unit 4 not shown here —see also FIG. 1—and enter into an electrical operative connection with the latter after assembly ready for use. It should be emphasized at this point that the embodiment shown here is to be regarded as an exemplary contacting and in no way as limiting the idea of the invention; thus it is of course also conceivable that only one of the pin contacts or two of the pin contacts are used and a third contacting is carried out via a housing element of the electronic cigarette. As mating contacts of the pin contacts, either surface contacts or zebra contacts are conceivable.

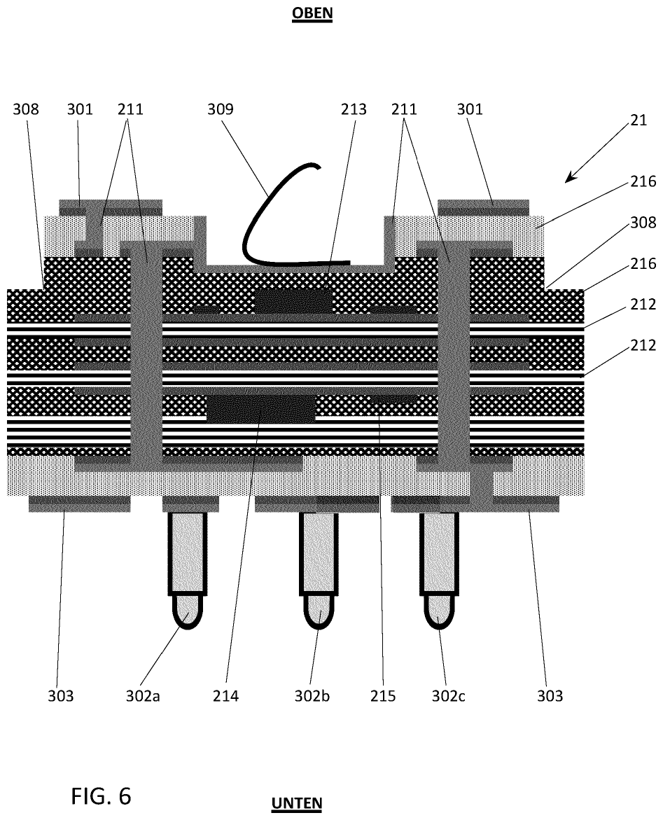

FIG. 6 discloses in a highly magnified sectional view a possible embodiment for the control unit 21 of the electronic cigarette 1 according to the invention. In its simplest form, this control unit 21 comprises at least one printed circuit board 212 equipped with a sensor 213 and/or one or more electrical components 215 and/or a microcontroller 214. FIG. 6 shows an exemplary structure based on embedded electronic components. In this embedding technology variant shown here, the components 213, 214, 215 which are later placed inside are soldered by means of a soldering process onto the respective copper layer which has been structured, for example, by etching, and are covered by cover layers of printed circuit board material 216 (prepregs) in the further printed circuit board manufacturing process. The copper layers onto which the components are soldered can either be individual foils or, as in the illustrated case, part of prepared two-layer or multilayer printed circuit boards comprising at least one insulator, e.g. comprising a cured prepreg 212 and two pressed-on copper layers. Depending on the design and material selection, for example, the resin in the cover layer materials may be used to fill voids around the embedded components during the subsequent PCB pressing process.

Other embedding technologies are available which also allow the processing of non-housed active electronic components, such as microcontrollers or ASICs, without an extra soldering process. In these technologies, standard processes from the PCB industry, e.g. microdrilling (HDI technology, microvias) and electroplating, are used for component contacting of the later internal electronic components. However, the basic structure with embedded components remains largely the same regardless of the embedded variant selected. Multilayer PCBs with embedded components can also be produced using the 3D printing/additive processes, e.g. on a paste/lacquer basis with drying or curing with UV light.

In addition to embedding electronic components, the use of PCB technology suitable for large-scale production also enables complex 3D structuring of the resulting assembly with standard machining processes while maintaining high precision or low tolerances. Mechanical guides and additional external contact elements can be very easily implemented in final PCB processes, such as connection surfaces for solder pins or a cavity for the contact spring 309.

The various layers of the multilayer printed circuit board with embedded electronic components are interconnected by means of through-platings 211 (microvias, vias) in a standard printed circuit board process and secure the electrical connections in the z-axis of the compact assembly.

A control unit of this type for the present electronic cigarette is distinguished from the prior art not only by improved miniaturization but also by lower energy consumption and lower power dissipation. In FIG. 6, the control unit 21 comprises a plurality of printed circuit boards 212 arranged insulated from one another and having embedded elements, such as the microcontroller 214, the sensor 213 and the electrical component 215, which these are intended to represent here merely as an example of further equivalent embodiments; typically, the printed circuit boards 212 arranged here horizontally and thus perpendicularly to the Z-axis are spaced apart by insulating fillings 216, with conductor tracks and through-platings 211 partially or completely electrically connecting the control unit 21.

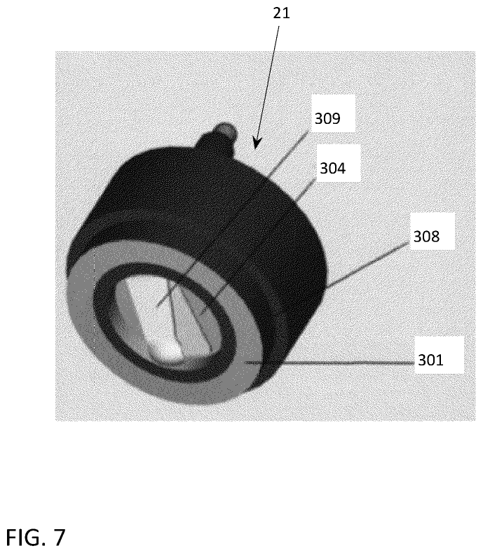

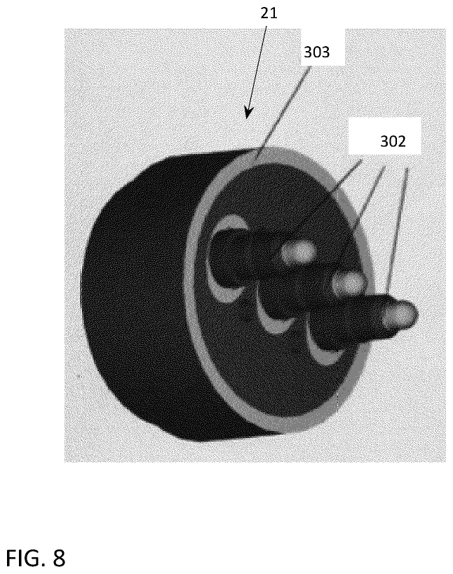

In FIG. 7, an exemplary embodiment of the control unit 21 is shown in a perspective view, in which one looks at the upper end of the control unit 21 with the +pole spring contact arranged thereon in a blind hole 304 and the corresponding −pole contact 301, which is formed in a ring shape in this case. This greatly enlarged representation is also able to substantiate the external impression of the control unit 21 as a “printed circuit board tablet”—already referred to above. FIG. 8 shows the embodiment of the control unit 21 according to FIG. 7 in a perspective view from below, namely with the spring contact pins 302 arranged there.

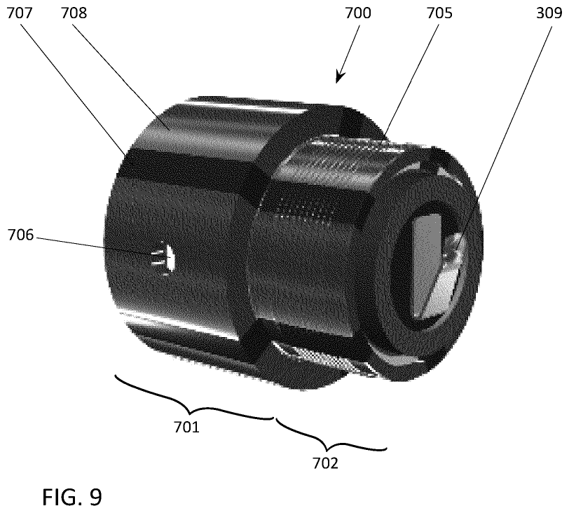

An embodiment of the closure component 700 is shown in FIG. 9 in a perspective side view with the +pole spring contact of the control unit 21 already enclosed terminating at the top. The closure component 700 shown here is subdivided in its longitudinal direction into a plurality of segments which act alternately in a conductive or insulating manner; thus, in each case a conductive element 708 abuts an insulator element 707 on both sides. Such segmentation opens up the possibility of forming conductive paths in the longitudinal direction by means of the closure component 700, which interact with a control unit inside which is suitably equipped for this purpose.

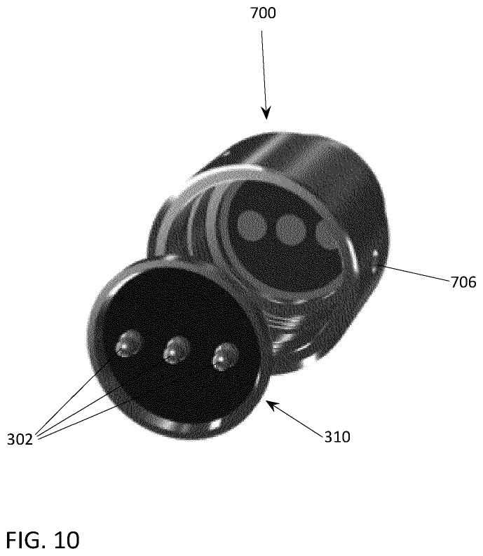

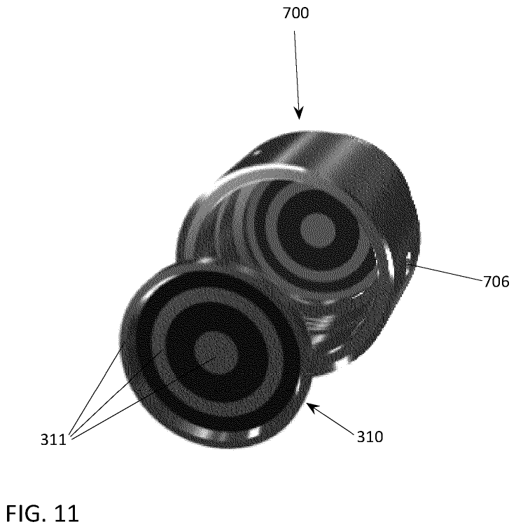

FIG. 10 shows a perspective view of a further embodiment looking at the lower end of the closure component 700, in which a contact carrier 310 is used, which contact carrier 310 is provided with spring pin contacts 302. A further embodiment of the contact carrier 310 is disclosed in FIG. 11, wherein this contact carrier 310—instead of pin contacts—is provided with surface contacts 311 (e.g. with spring action as a segmented contact made of conductive and non-conductive rubber), which in the present case are of annular or circular design.

Without abandoning the idea of the invention with respect to an efficient use of space of the control unit in an e-cigarette, it is also conceivable to arrange this control unit above the battery cell, or to partially provide the control unit on its outer casing with a number of flattenings in the form of distant circle segments or It is also conceivable to provide the control unit on its outer casing partially with a number of flattenings in the form of distant circle segments or circle sections, for example in order to provide a number of flow channels for a draught of air; it is of course also conceivable to provide an outer geometry of the battery casing which carries the geometry of the control unit described above with a number of distant circle segments to the outside. With regard to the contact pins used on the control unit, it should be emphasized that only a suitable embodiment of an electrical contact is meant here, which can be replaced in any way with identical function.

### LIST OF REFERENCE SIGNS

1 Electronic cigarette, e-cigarette
100 Battery sleeve
102 Internal thread on battery sleeve 100
110 Inner tube of battery sleeve 100, conductive stainless steel
111 Outer tube of battery sleeve 100, insulating
199 Battery unit
2 Control unit
21 Control unit, intelligence
22 Linear expansion of the 21
23 Diameter of the 21
200 Battery cell
202 +Pole
203 −Pole
204 Insulator ring at 200
205 −pole, upper termination of 200
206 lower finish of 200
209 Plastic foil, insulating
211 Track
212 Printed circuit board
213 Sensor
214 Microcontroller
215 Component
216 Insulation filling, prepreg
3 Locking unit
301 −pole contact an 21
302 Contact pin
302a −Pole contact pin
302b Communication contact pin, data connection, authentication
302c +pole contact pin
303 +pole contact surface or contact surfaces at 21
304 Blind hole in 21
306 Press ring
308 Milling
309 +pole contact on 21
310 contact carrier with ferrule
311 Surface contact
312 Sheath surface contact
4 Cartridge unit
600 Loading tip
601 +Pole Contact ring
602 Spring contact
603 −pole Contact tip
604 Ring insulator
700 Locking device
701 first section
702 second section
703 Overhang
704 Internal thread on closure component 700
705 External thread on closure component 700
706 Air inlet
707 Insulation element, longitudinally aligned
708 Guide element, longitudinally aligned

1.-11. (canceled)

12. An electronic cigarette comprising, along a central Z axis from bottom to top, a cartridge unit and a regulating unit detachably mounted thereon,
wherein the electronic cigarette further comprises a control unit for control and a battery unit for electronic power supply, the battery unit comprising a battery cell having a negative terminal and a positive terminal spaced therefrom by an insulator,
wherein a negative contact and a positive contact are arranged on the control unit in such a way that they are electrically operatively connected to the corresponding negative terminal and the positive contact of the battery cell respectively,
and wherein the control unit has a geometric spatial structure with a diameter perpendicular to the central Z axis that forms a fit in the electronic cigarette.

13. The electronic cigarette according to claim 12, wherein in that the fit formed between the electronic cigarette and the control unit is clearance fit, such that the control unit is slightly slidably arranged in the electronic cigarette.

14. The electronic cigarette according to claim 13, wherein the control unit has, facing towards the cartridge unit, at least one positive contact surface which is in operative electrical connection with an inner tube of the regulating unit.

15. The electronic cigarette according to claim 14, wherein the control unit is fixed in a closure component by a releasable press ring, the closure component being releasably arranged in the regulating unit, and wherein the at least one positive contact surface of the control unit is operatively connected to the inner tube of the regulating unit via the press ring and the closure component.

16. The electronic cigarette according to claim 1, wherein a fitting seat formed between the electronic cigarette and the control unit is configured as a transition fit, wherein the control unit can be inserted into the electronic cigarette with low pressure or can be extracted from the electronic cigarette with low pressure.

17. The electronic cigarette according to claim 16, wherein the control unit has a circumferential surface contact on an outer circumference, the circumferential surface contact forming the snug fit with a closure component and being in electrical operative connection with an inner tube of the regulating unit.

18. The electronic cigarette according to claim 12, wherein the control unit comprises at least one printed circuit board insulated from the electronic cigarette by means of an insulating filling, said at least one printed circuit board being oriented transversely to the Z axis.

19. The electronic cigarette according to claim 18, wherein the at least one printed circuit board has at least one sensor and/or at least one microcontroller and/or at least one electronic component that are electrically connected on the at least one printed circuit board and/or by means of a conductor track to the positive contact, the negative contact, the positive contact surface or an outer surface contact of the control unit.

20. The electronic cigarette according to claim 19, wherein the at least one sensor and/or the at least one microcontroller and/or the at least one electronic component are formed as an embedded, integrated electronic component with the at least one printed circuit board in the control unit.

21. The electronic cigarette according to claim 12, wherein the control unit has, extending towards the cartridge unit in ready-to-use assembly of the electronic cigarette, at least one contact pin which is electrically in operative connection with the cartridge unit.

22. The electronic cigarette according to claim 12, wherein the control unit comprises, extending towards the cartridge unit in ready-to-use assembly of the electronic cigarette, at least one positive contact pin, at least one negative contact pin, and one communication contact pin which are electrically in operative connection with the cartridge unit.
